(19) United States
(12) Patent Application Publication
(10) Pub. No.: US 2017/0227590 A1
(43) Pub. Date: Aug. 10, 2017

(54) HIGH IMPEDANCE ARC FAULT DETECTION

(71) Applicant: Hamilton Sundstrand Corporation, Charlotte, NC (US)

(72) Inventors: Waleed M. Said, Rockford, IL (US); Randall Bax, Rockton, IL (US)

(21) Appl. No.: 15/016,338

(22) Filed: Feb. 5, 2016

(51) Int. Cl. G01R 31/02; G06F 17/50; G01R 31/34

(52) U.S. Cl. CPC G01R 31/02; G01R 31/34; G06F 17/5036

(57) ABSTRACT

A motor controller circuit includes an electrical powertrain having a three phase input, a DC link and a three phase output, a controller including a processor and a memory, a first current sensor configured to sense a current at the three phase input, a second current sensor configured to sense a current at the three phase output, and a third sensor configured to sense a current at the DC link, and wherein the memory stores instructions configured to cause the processor to compare an operational model of the powertrain against a mathematical model of the powertrain and to detect a high impedance fault when a deviation between the operational model and the mathematical model exceeds a threshold.

### TECHNICAL FIELD

The present disclosure relates generally to arc fault detection, and more specifically to detection of a high impedance arc fault.

### BACKGROUND

Power conversion applications, such as those utilized in motor controllers, inherently include the possibility of arcing events where an electrically live component, such as a power terminal or a bus bar, arcs to another power terminal of different voltage or to a grounded housing or cold plate. Such arcing can occur for any number of reasons including, but not limited to, insufficient voltage withstand design margin, foreign objects component failure, manufacturing variability, manufacturing stresses, and contamination.

Typically, arc events are protected against via the inclusion of circuit breakers, fuses, or other similar fault protection devices. In operation, these types of fault protection devices trigger when a current through the fault protection device, or through a corresponding current sensor, exceeds a predetermined current threshold. When an arc event occurs and results in a circuit having a high impedance (high resistance to current flow), the current flow through the system can be lower than the trip threshold for the fault protection circuit. In such a case, the fault condition is not detected by the fault protection circuit, and damage resulting from the arc event can be compounded.

### SUMMARY OF THE INVENTION

An exemplary method for detecting a high impedance fault in an electrical circuit includes comparing an operational model of an electrical circuit against an expected operations model of the electrical circuit, and determining that a high impedance fault exists within the electrical circuit in response to a deviation between the operational model and the expected operations model by at least a predetermined amount.

Another example of the above described exemplary method for detecting a high impedance fault in an electrical circuit further includes activating fault protection circuit in response to determining that a high impedance fault exists.

Another example of any of the above described exemplary methods for detecting a high impedance fault in an electrical circuit includes activating a fault protection device comprises simulating a low impedance fault, thereby tripping the fault protection device.

Another example of any of the above described exemplary methods for detecting a high impedance fault in an electrical circuit includes simulating a low impedance fault comprises placing a DC/AC converter within the electrical circuit in a crowbar mode.

Another example of any of the above described exemplary method for detecting a high impedance fault in an electrical circuit further includes determining the operational model of the electrical circuit based at least in part on a measured input common mode current, a measured input differential mode current, a measured output common mode, a measured output differential mode current, a measured common mode current in a DC link, and a measured differential mode current in the DC link.

In another example of any of the above described exemplary methods for detecting a high impedance fault in an electrical circuit the operational model of the electrical circuit is further determined at least in part by at least one sensed voltage within the electrical circuit.

In another example of any of the above described exemplary methods for detecting a high impedance fault in an electrical circuit the expected operations model is a model of expected operations of the electrical circuit, and wherein the model is purely theoretical.

In another example of any of the above described exemplary methods for detecting a high impedance fault in an electrical circuit the expected operations model is a model of expected operations of the electrical circuit, and wherein the model is at least partial based on empirical operation sampling.

In another example of any of the above described exemplary methods for detecting a high impedance fault in an electrical circuit the expected operations model is a model of expected operations of the electrical circuit based on commanded parameters of the electrical circuit.

In another example of any of the above described exemplary methods for detecting a high impedance fault in an electrical circuit the commanded parameters include at least one of a commanded motor speed, a commanded torque, and a voltage applied to the electrical circuit.

In another example of any of the above described exemplary methods for detecting a high impedance fault in an electrical circuit the electrical circuit is a motor controller.

In another example of any of the above described exemplary methods for detecting a high impedance fault in an electrical circuit, the expected operations model is a mathematical model of expected electrical powertrain operations and the operational model is a mathematical model of actual electrical powertrain operations.

In another example of any of the above described exemplary methods for detecting a high impedance fault in an electrical circuit, the deviation between the operational model and the expected operations model is at least one of a deviation between at least one of a deviation between a common mode current of the three phase supply of the operational model and a common mode current of the three phase supply of the expected operations model; a deviation between a DC link common mode current of the operational model and a DC link common mode of the expected operations model; and a deviation between a value dependent on at least one of the common mode current of the three phase power supply and the DC link common mode current of each of the operational model and the expected operations model.

In one exemplary embodiment a motor controller circuit includes an electrical powertrain including a three phase input, a DC link and a three phase output, a controller including a processor and a memory, a first current sensor configured to sense a current at the three phase input, a second current sensor configured to sense a current at the three phase output, and a third sensor configured to sense a current at the DC link, and wherein the memory stores instructions configured to cause the processor to compare an operational model of the powertrain against an expected operations model of the powertrain and to detect a high impedance fault when a deviation between the operational model and the expected operations model exceeds a threshold.

Another exemplary embodiment of the above described motor controller circuit further includes a fault protection circuit connected to the three phase input.

In another exemplary embodiment of any of the above described motor controller circuits the faulty protection circuit is a fuse type circuit.

In another exemplary embodiment of any of the above described motor controller circuits the memory further includes instructions configured to cause the processor to activate a fault protection circuit in response to the threshold being exceeded.

In another exemplary embodiment of any of the above described motor controller circuits activating the fault protection circuit comprises simulating a low impedance fault.

In another exemplary embodiment of any of the above described motor controller circuits simulating a low impedance fault comprises placing a DC/AC converter within the powertrain in a crowbar mode.

These and other features of the present invention can be best understood from the following specification and drawings, the following of which is a brief description.

### BRIEF DESCRIPTION OF THE DRAWINGS

FIG. 1 schematically illustrates an exemplary motor controller system.

FIG. 2 schematically illustrates the motor controller electrical powertrain of FIG. 1 in more detail.

FIG. 3 schematically illustrates a controller process for controlling the powertrain of FIG. 2.

### DETAILED DESCRIPTION OF AN EMBODIMENT

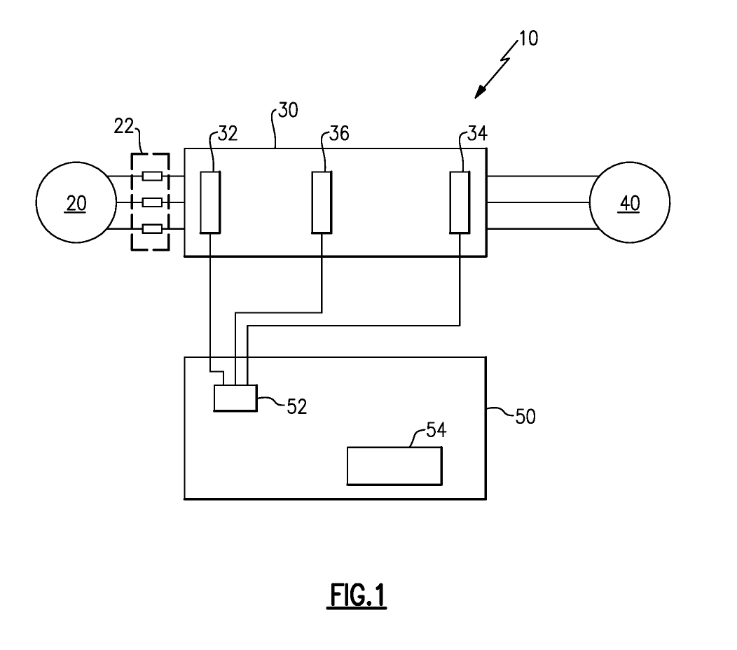

FIG. 1 schematically illustrates a motor controller system 10 including a three phase power source 20. The three phase power source 20 is connected to an electrical powertrain 30. The electrical powertrain 30 outputs three phase power to a motor 40, and drives the rotation of the motor 40. A controller 50 controls operation of the electrical powertrain 30, and thereby controls a voltage output to the motor 40. The voltage output to the motor 40, in turn, controls the rotational speed and the torque of the motor 40. The connections between the three phase power source 20 and the electrical powertrain 30 are fused connections 22 and are configured to trip (disconnect) when the current through the corresponding connection exceeds a threshold value. Typically, the threshold value is determined to be an expected low impedance fault value.

In alternative examples, the fused connections 22 can be replaced with any other fault detection and protection circuit. In such examples, additional current sensing and voltage sensing (not pictured) can be included within the electrical powertrain 30 as needed.

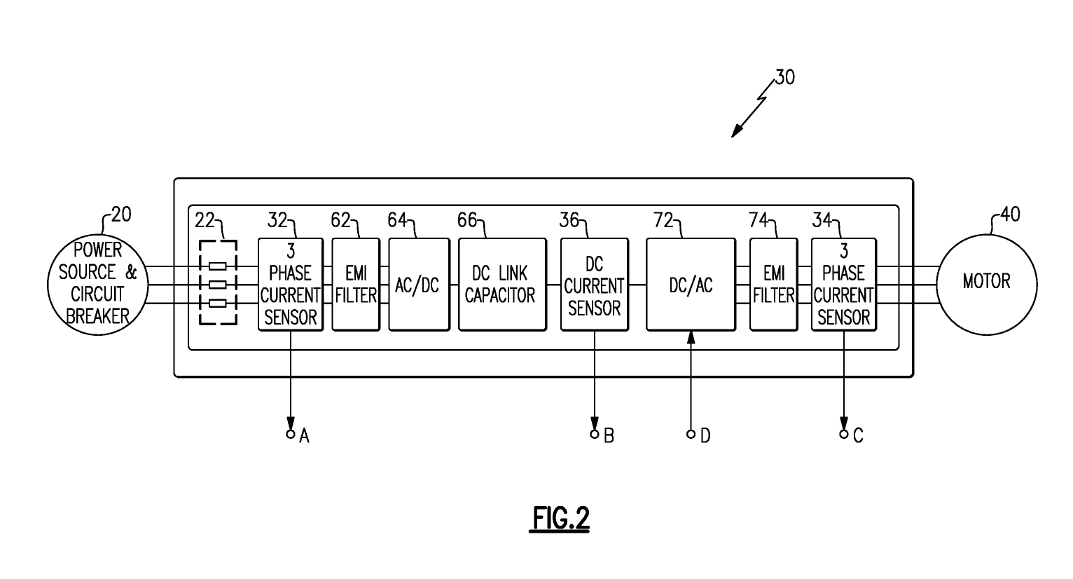

Included within the electrical powertrain 30 is an input current sensor 32 configured to sense an input current on each phase of the three phase power from the power source 20 and an output current sensor 34 configured to sense the output current on each phase that is provided to the motor 40. Connected to a DC link portion (illustrated in FIG. 2) is a DC current sensor 36. Each of the current sensors 32, 34, 36 provides a sensed output to the motor controller 50. In one exemplary implementation, the motor controller 50 includes a processor 52, and a memory 54. The processor 52 and memory 54 are configured to generate a pulse width modulation (PWM) signal to control the motor controller electrical powertrain 30 according to known PWM control principles.

With continued reference to FIG. 1, FIG. 2 schematically illustrates the internal components of the electrical powertrain 30, according to one example embodiment, in more detail. As illustrated in FIG. 1, a three phase power source 20 is connected to the electrical powertrain 30 via a fused connection 22. A three phase input current sensor 32 senses the input currents and provides the current magnitude to the controller 50 (illustrated in FIG. 1) via a sensor output A.

The three phase power is passed through the input current sensor 32 to an EMI (electromagnetic interference) filter 62. The EMI filter 62 removes electromagnetic noise from the three phase power input, and outputs “clean” three phase power.

The clean three phase power is provided to an AC/DC converter 64. The AC/DC converter 64 converts the three phase power to a DC power output, and provides the DC power output to a DC link capacitor 66. The DC link capacitor 66 ensures that any ripples, or other variations in the DC power output by the AC/DC converter 64, are smoothed and provides an output DC power to a DC current sensor 36. A sensed output of the DC current sensor 36 is provided to the controller 50 via a sensor output B.

A DC/AC converter 72 converts the DC voltage that passes through the DC current sensor 36 into a three phase power output, and provides the three phase power output to a second EMI filter 74. The DC/AC converter 72 includes a network of transistors that are operated by a PWM signal output from the controller 50 and received at a PWM signal input D.

The output of the EMI filter 74 is passed through a three phase current sensor 34 and drives the motor 40 to rotate. As with the input current sensor 32, the output current sensor 34 provides the sensed current information to the controller 50 via a sensor output C.

During operation of the electrical powertrain 30, an arc event can occur. An arc event is a condition where electrical current arcs (leaps via a spark) from an electrically live component another live component or to a neutral component. Arc events can occur due to excess voltages, stresses within the housing structure, manufacturing defects, or any number of other conditions. The arcing damages the components exposed to the electrical arc and can, in some instances, heats the housing or other neutral components beyond their melting points creating holes in the structure of the housing or other neutral components. As described above, typical fault detection and prevention circuits, such as the fused connection 22 illustrated in FIGS. 1 and 2, trip when a current through the protection circuit, or at a sensed location, exceeds a preset threshold.

Arc faults, such as those that can occur within the electrical powertrain 30 are in some cases high impedance arc faults. A high impedance arc fault is a continuous arc fault that has a relatively high resistance to current flow. As a result, the current through the fault detection circuit is not increased above the fault detection threshold and a fault is never registered. As a fault is never registered, the fault detection circuit does not trip. Absent some additional method for detecting a high impedance fault, the arcing is allowed to continue, compounding any damage that is generated as a result of the arc fault.

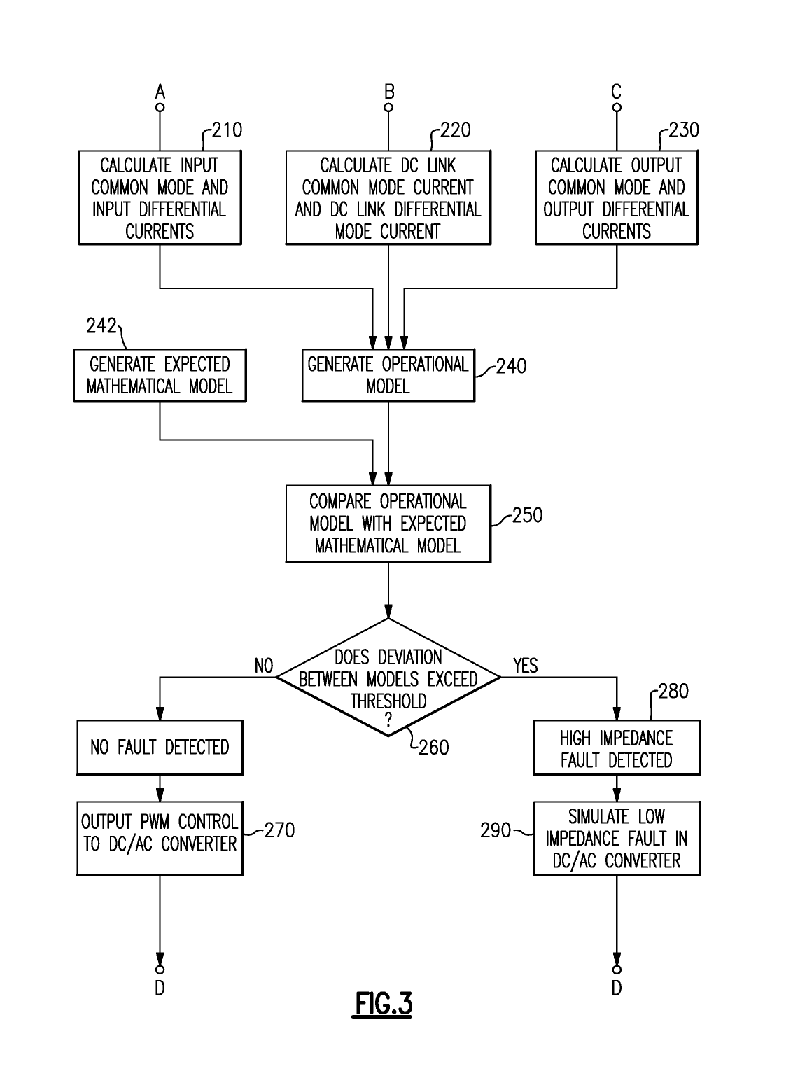

With continued reference to FIGS. 1 and 2, FIG. 3 illustrates an exemplary process by which the controller processor 52 (illustrated in FIG. 1) can detect and respond to a high impedance arc fault occurrence within a electrical powertrain 30. Initially the sensed output values are provided from the current sensors 32, 36, 34 to the processor 52 via the sensor output lines A, B and C. The processor 52 then simultaneously, or approximately simultaneously, calculates a common mode current and a differential mode current from each sensor based on the sensed values received via the sensor links A, B, and C in “Calculate Common Mode and Differential Mode Current” processes 210, 220 and 230. The differential mode component of the current is the direct measurement of the corresponding sensor 32, 34, 36. Calculating the common mode component of the current can be achieved by the following equation:

I_{cm}=Iₐ+I_{b}+I_{c}

Where I_{cm} is the common mode current, I_{a,b,c} are the currents in phases a, b, c respectively of the three phase supply.

The common mode current from the DC link sensor can be calculated using the following equation:

I_{cm dc}=I_{dc+}+I_{dc-}

Where L_{cm dc} is the common mode current in the DC link and I_{dc+} and I_{dc-} are the positive and negative currents in the DC link.

Once the common mode and differential mode currents from each sensor link A, B, and C are determined, the processor 52 generates an operational model of the electrical powertrain 30 in a “Generate Operational Model” process 240. The operational model is a mathematical model of the operations of the electrical powertrain 30, and is generated according to any known mathematical modeling system. In some example embodiments, additional sensors can be included within the electrical powertrain 30 beyond the current sensors illustrated in FIGS. 1 and 2. By way of example, input voltage sensors, output voltage sensors, and the like can be included. When additional sensors are present, the operational model can utilize the additional sensed data to obtain a higher fidelity (more accurate) operational model. One of skill in the art, having the benefit of this disclosure, will recognize that inclusion of additional sensed data in the calculation of the operational model will necessarily increase the delay between an occurrence of an arc fault and the arc fault's detection.

Other example embodiments may change the location of the sensor. One example of which, locates the DC current sensor 30 between the AC/DC converter 64 and the DC link capacitor 66. One of skill in the art, having the benefit of this disclosure, will recognize that this alternative measurement location will provide a common mode current that can be calculated as described above. This alternative example embodiment can, in some cases, provide a cost savings when the sensors are additionally used for control of the AC/DC converter 64 along with the common mode current calculation.

Simultaneously with the generation of the operational model, the processor 52 generates an expected mathematical model in a “Generate Expected Mathematical Model” process 242. The expected mathematical model is a theoretical mathematical model of the expected operations of the electrical powertrain 30 based on the parameters set by the controller 50. By way of example, the parameters can include a commanded speed of the motor 40, a commanded torque of the rotor and a commanded voltage output of the electrical powertrain 30. As with the operational model, the expected theoretical model is generated using any known modeling technique. In some examples, the expected mathematical model is purely conceptual and is based solely on ideal component calculations. In other examples, the expected mathematical model is based at least in part on empirical operations data generated from one or more physical powertrains.

Once the expected mathematical model and the operational model are generated, the processor 52 compares the operational model against the expected mathematical model, and determines a magnitude of deviation between the two models in a “Compare Model With Expected Mathematical Model” process 250. The magnitude of the deviation is then compared against a threshold value in a “Does Deviation Between Models Exceed Threshold” check 260. In some examples, the deviation is a deviation between a common mode current of the three phase supply, a DC link common mode current, or a value dependent on one or both of the common mode current of the three phase power supply and the DC link common mode current.

If the deviation between the models does not exceed the threshold, no fault is detected in the operation of the electrical powertrain 30, and the controller 50 continues to output pulse width modulation (PWM) controls to the DC/AC converter 72 in an “Output PWM Control to DC/AC Converter” process 270.

In contrast, if the deviation between the models exceeds the threshold, a high impedance fault is detected in a “High Impedance Fault Detected” process 280. Once the high impedance fault is detected, the controller 50 trips the fault protection circuit (the fused connection 22), thereby preventing continued operation of the faulted electrical powertrain 30. In some examples, such as those where the fault protection circuit is a fuse style fault protection circuit, the controller 50 cannot directly trip the fault protection circuit. In such examples, the controller 50 operates the DC/AC converter 72 in a manner that simulates a low impedance fault in a “Simulate Low Impedance Fault in DC/AC Converter” process 290.

In order to simulate a low impedance fault, the controller 50 in one example commands each of the transistors in the DC/AC converter 72 to close simultaneously. As a result of the simultaneously closed transistors, the DC/AC converter 72 acts as a short across the DC link, allowing for a large current spike to be generated. The large current spike is sufficient to trip a fuse style fault protection circuit, or any similar fault protection circuit. Operating the transistors within the DC/AC converter 72 in this manner is referred to as crowbarring the DC/AC converter.

While described above with regards to operations within a motor controller, one of skill in the art will recognize that the system and process described herein can be applied to any electrical device or component susceptible to high impedance arc faulting, and is not limited to motor controller applications.

It is further understood that any of the above described concepts can be used alone or in combination with any or all of the other above described concepts. Although an embodiment of this invention has been disclosed, a worker of ordinary skill in this art would recognize that certain modifications would come within the scope of this invention. For that reason, the following claims should be studied to determine the true scope and content of this invention.

1. A method for detecting a high impedance fault in an electrical circuit comprising:
comparing an operational model of an electrical circuit against an expected operations model of the electrical circuit; and
determining that a high impedance fault exists within the electrical circuit in response to a deviation between the operational model and the expected operations model by at least a predetermined amount.

2. The method of claim 1, further comprising activating fault protection circuit in response to determining that a high impedance fault exists.

3. The method of claim 2, wherein activating a fault protection device comprises simulating a low impedance fault, thereby tripping the fault protection device.

4. The method of claim 3, wherein simulating a low impedance fault comprises placing a DC/AC converter within the electrical circuit in a crowbar mode.

5. The method of claim 1, further comprising determining the operational model of the electrical circuit based at least in part on a measured input common mode current, a measured input differential mode current, a measured output common mode, a measured output differential mode current, a measured common mode current in a DC link, and a measured differential mode current in the DC link.

6. The method of claim 5, wherein the operational model of the electrical circuit is further determined at least in part by at least one sensed voltage within the electrical circuit.

7. The method of claim 1, wherein the expected operations model is a model of expected operations of the electrical circuit, and wherein the model is purely theoretical.

8. The method of claim 1, wherein the expected operations model is a model of expected operations of the electrical circuit, and wherein the model is at least partial based on empirical operation sampling.

9. The method of claim 1, wherein the expected operations model is a model of expected operations of the electrical circuit based on commanded parameters of the electrical circuit.

10. The method of claim 9, wherein the commanded parameters include at least one of a commanded motor speed, a commanded torque, and a voltage applied to the electrical circuit.

11. The method of claim 1, wherein the electrical circuit is a motor controller.

12. The method of claim 1, wherein the expected operations model is a mathematical model of expected electrical powertrain operations and the operational model is a mathematical model of actual electrical powertrain operations.

13. The method of claim 1, wherein the deviation between the operational model and the expected operations model is at least one of:
a deviation between a common mode current of the three phase supply of the operational model and a common mode current of the three phase supply of the expected operations model;
a deviation between a DC link common mode current of the operational model and a DC link common mode of the expected operations model; and
a deviation between a value dependent on at least one of the common mode current of the three phase power supply and the DC link common mode current of each of the operational model and the expected operations model,

14. A motor controller circuit comprising:
an electrical powertrain including a three phase input, a DC link and a three phase output;
a controller including a processor and a memory;
a first current sensor configured to sense a current at the three phase input, a second current sensor configured to sense a current at the three phase output, and a third sensor configured to sense a current at the DC link; and
wherein the memory stores instructions configured to cause the processor to compare an operational model of the powertrain against an expected operations model of the powertrain and to detect a high impedance fault when a deviation between the operational model and the expected operations model exceeds a threshold.

15. The motor controller of claim 14, further comprising a fault protection circuit connected to said three phase input.

16. The motor controller of claim 15, wherein the faulty protection circuit is a fuse type circuit.

17. The motor controller of claim 14, wherein the memory further includes instructions configured to cause the processor to activate a fault protection circuit in response to the threshold being exceeded.

18. The motor controller of claim 17, wherein activating the fault protection circuit comprises simulating a low impedance fault.

19. The motor controller of claim 18, wherein simulating a low impedance fault comprises placing a DC/AC converter within said powertrain in a crowbar mode.
